(19) United States
(12) Patent Application Publication
(10) Pub. No.: US 2006/0170478 A1
(43) Pub. Date: Aug. 3, 2006

(54) Delay circuit for semiconductor device

(75) Inventor: Bu-Il Jung, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/344,844

(22) Filed: Feb. 1, 2006

(30) Foreign Application Priority Data
Feb. 2, 2005 (KR) 05-9481

(51) Int. Cl. H03H 11/26

(52) U.S. Cl. 327/276

(57) ABSTRACT

A delay circuit for a semiconductor device includes a variable resistor unit having a resistance value adjusted in response to a control signal, and a variable load unit having a capacitance value adjusted in response to the control signal. The delay circuit of the present invention includes a variable resistor unit having a variable resistance value and a variable load unit having a variable capacitance value. The delay circuit for a semiconductor device can precisely adjust the delay time of a signal. Further, the capacitance of the variable load unit is very low in an operation mode in which the delay circuit of the present invention is controlled so that it has a short delay time. Therefore, the delay time can be adjusted to a short time by the delay circuit of the present invention.

### RELATED APPLICATION

This application relies for priority on Korean patent application number 10-2005-0009481, filed in the Korean Intellectual Property Office on Feb. 2, 2005, the entire contents of which are incorporated herein by reference.

### BACKGROUND OF THE INVENTION

1. Field of the Invention

The present invention relates, in general, to a circuit for a semiconductor device and, more particularly, to a delay circuit for a semiconductor device, which delays a signal and controls the timing of the signal.

2. Description of the Related Art

Generally, a semiconductor device includes therein a delay circuit for controlling the timing between internal signals or between an externally applied clock and an internal clock. Typically, semiconductor devices are required to be operated in a wide frequency band with high precision. Therefore, a delay circuit included in a semiconductor device is also required to delay a signal in a wide frequency band with high precision.

A conventional delay circuit is constructed in such a way that a plurality of logic circuits (an inversion circuit, a NAND circuit, etc.) are connected in series. Further, the delay time of a signal is adjusted by increasing or decreasing the number of stages of logic circuits through which the signal passes. That is, a conventional delay circuit adjusts the delay time of a signal according to the number of stages of logic circuits through which the signal passes.

However, in the conventional delay circuit, a delay time is adjusted with the unit of the delay time in a single logic circuit. Therefore, the conventional delay circuit is problematic in that it is impossible to adjust the delay time finely.

### SUMMARY OF THE INVENTION

Accordingly, a feature of the present invention is to provide a delay circuit for a semiconductor device, which can precisely adjust the delay time of a signal.

In one aspect, the present invention provides a delay circuit for a semiconductor device. The delay circuit comprises an inverter, first and second variable resistor units, and first and second variable load units. The inverter inverts an input signal and provides inversion results as an output signal. The inverter has a pull-up terminal for receiving a control current and a pull-down terminal for discharging the control current. The first variable resistor unit is arranged between a supply voltage and the pull-up terminal of the inverter to provide a control current to the inverter using a first resistance value. The first resistance value is adjusted in response to a control signal. The second variable resistor unit is arranged between a ground voltage and the pull-down terminal of the inverter to discharge the control current from the inverter using a second resistance value. The second resistance value is adjusted in response to the control signal. The first variable load unit is connected to an output signal of the inverter and has a capacitance adjusted in response to the control signal. The second variable load unit is connected to the output signal of the inverter and has a capacitance adjusted in response to the control signal. The second variable load unit is driven to improve symmetry of pull-up and pull-down characteristics of the output signal of the inverter.

In one embodiment, (i) the first variable resistor unit comprises a first resistor arranged between the supply voltage and the pull-up terminal of the inverter and a PMOS transistor connected in parallel with the first resistor and controlled in response to the control signal; and (ii) the second variable resistor unit comprises a second resistor arranged between the ground voltage and the pull-down terminal of the inverter and an NMOS transistor connected in parallel with the second resistor and controlled in response to the control signal.

In one embodiment, (i) the first variable load unit comprises a PMOS transistor that is controlled in response to the output signal of the inverter, a voltage of source/drain terminals of the PMOS transistor being controlled by the control signal; and (ii) the second variable load unit comprises an NMOS transistor that is controlled in response to the output signal of the inverter, a voltage of source/drain terminals of the NMOS transistor being controlled by the control signal.

In one embodiment, the control signal has a logic state controlled by a mode register set.

In one embodiment, the control signal has a logic state controlled depending on whether a predetermined fuse is cut.

According to another aspect, the invention is directed to a delay circuit for a semiconductor device for delaying a signal. The delay circuit includes an inverter, first and second resistors, first and second PMOS transistors and first and second NMOS transistors. The inverter inverts the signal and outputs an inverted signal. The inverter has a pull-up terminal for receiving a pull-up voltage and a pull-down terminal for receiving a pull-down voltage. The first resistor is arranged between a supply voltage and the pull-up terminal of the inverter. The first PMOS transistor is connected in parallel with the first resistor and is controlled in response to a control signal. The second resistor is arranged between a ground voltage and the pull-down terminal of the inverter. The first NMOS transistor is connected in parallel with the second resistor and is controlled in response to the control signal. The second PMOS transistor is controlled in response to an output signal of the inverter and has source/drain terminals, a signal at a logic state equal to that of a signal for controlling the first PMOS transistor being applied to the source/drain terminals of the second PMOS transistor. The second NMOS transistor is controlled in response to the output signal of the inverter and has source/drain terminals, a signal at a logic state equal to that of a signal for controlled the first NMOS transistor being applied to the source/drain terminals of the second NMOS transistor.

In one embodiment, the control signal has a logic state controlled by a mode register set.

In one embodiment, the control signal has a logic state controlled depending on whether a predetermined fuse is cut.

According to another aspect, the invention is directed to a delay circuit for a semiconductor device for delaying a signal. The delay circuit includes a logic circuit for adjusting a response time of the signal according to a magnitude of a supplied control current. A variable resistor unit supplies the control current to the logic circuit, the control current being adjusted according to a resistance value of the variable resistor unit, the resistance value being adjusted in response to a control signal. A variable load unit has a variable capacitance value and is connected to an output terminal of the logic circuit, the capacitance value being adjusted in response to the control signal.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a circuit diagram showing the principle of a delay circuit for a semiconductor device according to the present invention.

FIG. 2 is a circuit diagram showing an example of a delay circuit for a semiconductor device embodying the principle of FIG. 1.

FIG. 3 is a circuit diagram showing a delay circuit for a semiconductor device according to an embodiment of the present invention.

FIG. 4 is a circuit diagram showing a delay circuit for a semiconductor device according to another embodiment of the present invention.

### DESCRIPTION OF THE PREFERRED EMBODIMENTS

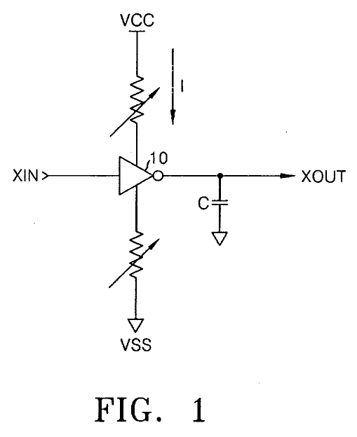

FIG. 1 is a circuit diagram showing the principle of a delay circuit for a semiconductor device according to the present invention. In accordance with the invention, the delay circuit of FIG. 1 adjusts the or magnitude of a control current I supplied to an inverter 10, thus adjusting a delay time td. That is, the magnitude of the control current I increases or decreases, so that the charging time of a load capacitor C in the next stage of the inverter 10 is adjusted. Consequently, a time for which an output signal XOUT reaches a logic threshold level is adjusted.

For example, if it is assumed that a delay time is td1 when the magnitude of the control current is I1, and a delay time is td2 when the magnitude of the control current is I2, the following Equation [1] is constructed.
I1×td1=I2×td2=C×Vt [1]

In Equation [1], C refers to the capacitance of capacitor C and Vt refers to the logic threshold voltage level.

If I1>I2 is satisfied, td1<td2 is obtained. That is, as the magnitude of the control current I1 increases, the delay time td decreases.

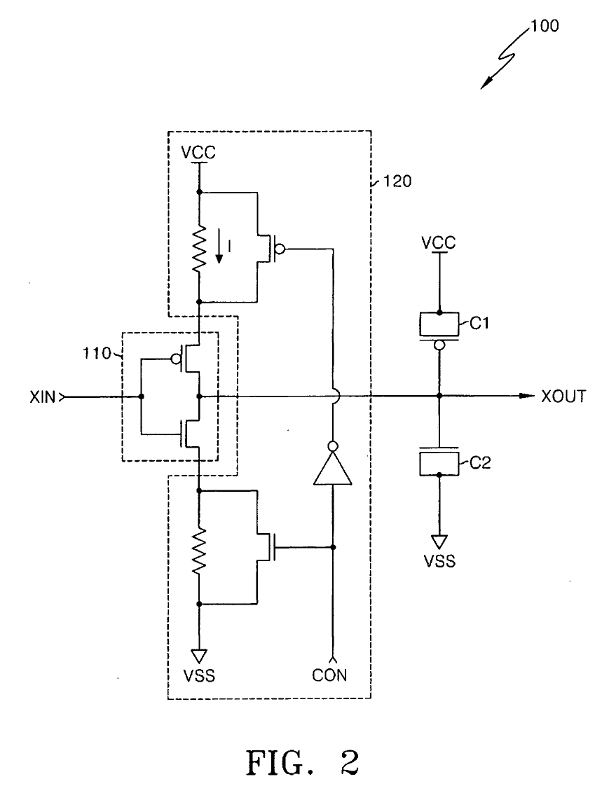

FIG. 2 is a circuit diagram showing an example of a delay circuit 100 for a semiconductor device for realizing the principle of FIG. 1. Referring to FIG. 2, the delay circuit 100 includes an inverter 110 for inverting the logic state of an input signal XIN and generating an output signal XOUT, a variable resistor unit 120 for adjusting a control current I supplied to the inverter 110 and controlling the delay time of the input signal, and capacitors C1 and C2 for storing electric charges from the output signal XOUT.

In the delay circuit 100 of FIG. 2, when a control signal CON is in a logic H level, the control current I, supplied from a supply voltage VCC to the inverter 110, is relatively high. Therefore, a delay time td generated by the inverter 110 is relatively short.

Further, when the control signal CON is in a logic L level, the control current I, supplied from the supply voltage VCC to the inverter 110, is relatively low. Therefore, the delay time td generated by the inverter 110 is relatively long.

In this way, in the delay circuit 100 of FIG. 2, the delay time td is controlled according to the logic state of the control signal CON. The delay time td can be controlled within a unit delay time of a logic circuit. Therefore, the delay circuit 100 of FIG. 2 can control a delay time more finely than a conventional delay circuit that controls a delay time by increasing or decreasing the number of stages of logic circuits.

The capacitors C1 and C2 of the delay circuit 100 of FIG. 2 always act as loads with respect to the output signal XOUT of the inverter 110. Therefore, the delay circuit 100 of FIG. 2 cannot shorten the delay time td to a predetermined level or lower due to the capacitances of the capacitors C1 and C2. Therefore, a semiconductor device employing the delay circuit 100 of FIG. 2 may exhibit the phenomenon that that an operating speed may decrease due to the capacitors C1 and C2 that always act as loads.

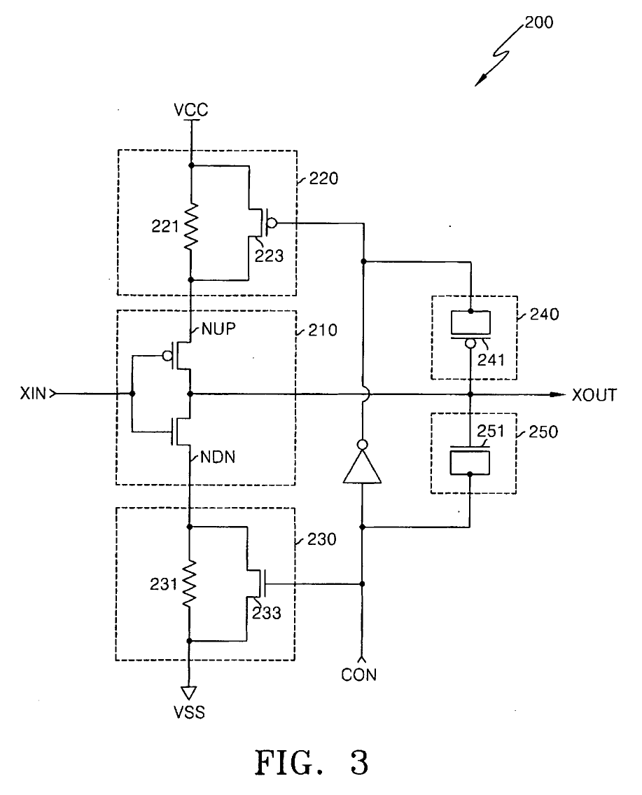

FIG. 3 is a circuit diagram showing a delay circuit 200 for a semiconductor device according to an embodiment of the present invention in which this potential problem is solved. Referring to FIG. 3, the delay circuit 200 of the present invention includes an inverter 210, a first variable resistor unit 220, a second variable resistor unit 230, a first variable load unit 240 and a second variable load unit 250.

The inverter 210 inverts an input signal XIN and provides inversion results as an output signal XOUT. The inverter 210 receives a control current required to control the output signal XOUT through a pull-up terminal NUP, and discharges the control current required to control the output signal XOUT through a pull-down terminal NDN.

The first variable resistor unit 220 is arranged between the supply voltage VCC and the pull-up terminal NUP of the inverter 210, and supplies the control current to the inverter 210. In this case, the resistance value of the first variable resistor unit 220 is adjusted in response to a control signal CON.

Preferably, the first variable resistor unit 220 includes a resistor 221 and a PMOS transistor 223. The resistor 221 is arranged between the supply voltage VCC and the pull-up terminal NUP of the inverter 210. Further, the PMOS transistor 223 is connected in parallel with the resistor 221 between the supply voltage VCC and the pull-up terminal NUP of the inverter 210. In this case, the PMOS transistor 223 is controlled in response to an inverted signal of the control signal CON. In this embodiment, when the control signal CON is in a logic H level, the PMOS transistor 223 is turned on. Therefore, the actual resistance value of the first variable resistor unit 220 decreases.

The second variable resistor unit 230 is arranged between a ground voltage VSS and the pull-down terminal NDN of the inverter 210, and discharges the control current from the inverter 210. The resistance value of the second variable resistor unit 230 is adjusted in response to the control signal CON.

Preferably, the second variable resistor unit 230 includes a resistor 231 and an NMOS transistor 233. The resistor 231 is arranged between the ground voltage VSS and the pull-down terminal NDN of the inverter 210. The NMOS transistor 233 is connected in parallel with the resistor 231 between the ground voltage VSS and the pull-down terminal NDN of the inverter 210. The NMOS transistor 233 is controlled in response to the control signal CON. In this embodiment, when the control signal CON is in a logic H level, the NMOS transistor 233 is turned on, so that the actual resistance value of the second variable resistor unit 230 decreases.

The first and second variable load units 240 and 250 are connected to the output signal XOUT of the inverter 210. The capacitances of the first and second variable load units 240 and 250 are adjusted in response to the control signal CON. Preferably, the first variable load unit 240 includes a PMOS transistor 241 controlled in response to the output signal XOUT of the inverter 210. The second variable load unit 250 includes an NMOS transistor 251 controlled in response to the output signal XOUT of the inverter 210. The inverted signal of the control signal CON is applied to the source/drain terminals of the PMOS transistor 241. The control signal CON is applied to the source/drain terminals of the NMOS transistor 251.

Therefore, when the control signal CON makes a transition to a logic L level, both the PMOS transistor 241 and the NMOS transistor 251 act as capacitors, and the capacitances of the first and second variable load units 240 and 250 are adjusted to high values. In contrast, when the control signal CON makes a transition to a logic H level, the capacitances of the first and second variable load units 240 and 250 are adjusted to very low values.

Consequently, when the control signal CON makes a transition to a logic H level (in an operation mode in which the delay circuit of the present invention is controlled so that it has a short delay time), the capacitances of the first and second variable load units 240 and 250 become very low. In this case, the delay time generated by the delay circuit of the present invention is adjusted to a very short time.

In contrast, when the control signal CON makes a transition to a logic L level (in an operation mode in which the delay circuit of the present invention is controlled so that it has a long delay time), the PMOS transistor 241 and the NMOS transistor 251 of the first and second variable load units 240 and 250 form capacitors, respectively. Therefore, a delay time is obtained by the first and second variable load units 240 and 250.

In the embodiment of FIG. 3, the first and second variable load units 240 and 250 are driven so that the pull-up and pull-down characteristics of the output signal XOUT of the inverter 210 are symmetrically formed.

In the embodiment of FIG. 3, the first and second variable resistor units 220 and 230 can be collectively designated as a “variable resistor unit”. The first and second variable load units 240 and 250 can be collectively designated as a “variable load unit”. It will be understood that a circuit using a NAND gate, a NOR gate, etc., instead of the inverter 210, can be used in accordance with the invention.

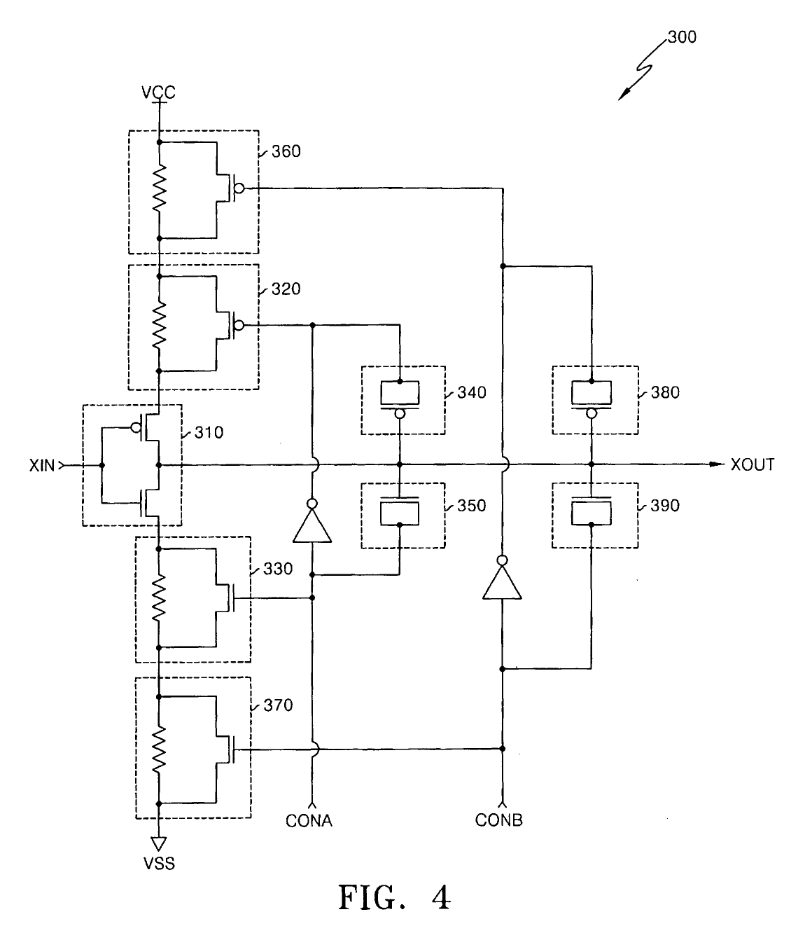

FIG. 4 is a circuit diagram of a delay circuit 300 for a semiconductor device according to another embodiment of the present invention, which shows an extended embodiment of the embodiment of FIG. 3. The delay circuit 300 of FIG. 4 includes an inverter 310, and two variable resistor units 320 and 330 and two variable load units 340 and 350 that are controlled by a first control signal CONA. Further, the delay circuit 300 of FIG. 4 includes two variable resistor units 360 and 370 and two variable load units 380 and 390 that are controlled by a second control signal CONB.

The structure and function of the portions of the circuit of FIG. 4 including the inverter 310, variable resistor units 320 and 330 and variable load units 340 and 350, controlled by the first control signal CONA, are similar to those described in connection with the embodiment of FIG. 3. Therefore, detailed description of these elements will not be repeated.

As noted above, the delay circuit 300 of FIG. 4 includes two variable resistor units 360 and 370 and two variable load units 380 and 390 that are controlled by a second control signal CONB in a manner similar to the manner in which the first control signal CONA controls the variable resistor units 320 and 330 and the two variable load units 340 and 350. As a result, the additional circuits 360, 370, 380 and 390, and the control signal CONB provide the circuit of FIG. 4 with the capability to more precisely control the delay introduced by the circuit 300. For example, if the CONA and CONB control signals are controlled such that both PMOS transistors in variable resistor units 320, 360 and both NMOS transistors in variable resistor units 330, 370 are on, then the maximum current will flow into the inverter 310. If the control signals CONA and CONB are controlled such that all of the transistors in the variable resistor units are off, then the minimum current flows in the inverter 310. Also, the CONA and CONB signals can be controlled such that only one of the PMOS transistors in the variable resistor units 320, 360 and only one of the NMOS transistors in the variable resistor units 330, 370 is on. This results in a current between the maximum and minimum flowing in the inverter 310. Likewise, the control signals CONA and CONB can be timed to provide an additional level of adjustment precision to the capacitances in the variable load units 340, 350, 380 and 390.

Therefore, the embodiment of FIG. 4 can control a delay time at various intervals compared to the embodiment of FIG. 3.

As described above, the present invention provides a delay circuit for a semiconductor device, which includes a variable resistor unit having a variable resistance value, and a variable load unit having a variable capacitance value. Therefore, the delay circuit for a semiconductor device can precisely adjust the delay time of a signal.

Further, the present invention is advantageous in that the capacitance of the variable load unit becomes very low in an operation mode in which the delay circuit of the present invention is controlled so that it has a short delay time. In this case, the delay time can be adjusted to a very short time by the delay circuit of the present invention.

Although the preferred embodiments of the present invention have been disclosed for illustrative purposes, those skilled in the art will appreciate that various modifications, additions and substitutions are possible, without departing from the scope and spirit of the invention as defined in the accompanying claims.

What is claimed is:

1. A delay circuit for a semiconductor device, comprising:
an inverter for inverting an input signal and providing inversion results as an output signal, the inverter having a pull-up terminal for receiving a control current and a pull-down terminal for discharging the control current;
a first variable resistor unit arranged between a supply voltage and the pull-up terminal of the inverter to supply a control current to the inverter using a first resistance value, the first resistance value being adjusted in response to a control signal;
a second variable resistor unit arranged between a ground voltage and the pull-down terminal of the inverter to discharge the control current from the inverter using a second resistance value, the second resistance value being adjusted in response to the control signal;
a first variable load unit connected to an output signal of the inverter and having a capacitance adjusted in response to the control signal; and
a second variable load unit connected to the output signal of the inverter and having a capacitance adjusted in response to the control signal, the second variable load unit being driven to improve symmetry of pull-up and pull-down characteristics of the output signal of the inverter.

2. The delay circuit according to claim 1, wherein:
the first variable resistor unit comprises a first resistor arranged between the supply voltage and the pull-up terminal of the inverter and a PMOS transistor connected in parallel with the first resistor and controlled in response to the control signal; and
the second variable resistor unit comprises a second resistor arranged between the ground voltage and the pull-down terminal of the inverter and an NMOS transistor connected in parallel with the second resistor and controlled in response to the control signal.

3. The delay circuit according to claim 1, wherein:
the first variable load unit comprises a PMOS transistor that is controlled in response to the output signal of the inverter, a voltage of source/drain terminals of the PMOS transistor being controlled by the control signal, and
the second variable load unit comprises an NMOS transistor that is controlled in response to the output signal of the inverter, a voltage of source/drain terminals of the NMOS transistor being controlled by the control signal.

4. A delay circuit for a semiconductor device for delaying a signal, comprising:
an inverter for inverting the signal and outputting an inverted signal, the inverter having a pull-up terminal for receiving a pull-up voltage and a pull-down terminal for receiving a pull-down voltage;
a first resistor arranged between a supply voltage and the pull-up terminal of the inverter;
a first PMOS transistor connected in parallel with the first resistor and controlled in response to a control signal;
a second resistor arranged between a ground voltage and the pull-down terminal of the inverter;
a first NMOS transistor connected in parallel with the second resistor and controlled in response to the control signal;
a second PMOS transistor that is controlled in response to an output signal of the inverter and having source/drain terminals, a signal at a logic state equal to that of a signal for controlling the first PMOS transistor being applied to the source/drain terminals of the second PMOS transistor; and
a second NMOS transistor that is controlled in response to the output signal of the inverter and having source/drain terminals, a signal at a logic state equal to that of a signal for controlled the first NMOS transistor being applied to the source/drain terminals of the second NMOS transistor.

5. A delay circuit for a semiconductor device for delaying a signal, comprising:
a logic circuit for adjusting a response time of the signal according to a magnitude of a supplied control current;
a variable resistor unit for supplying the control current to the logic circuit, the control current being adjusted according to a resistance value of the variable resistor unit, the resistance value being adjusted in response to a control signal; and
a variable load unit having a variable capacitance value and connected to an output terminal of the logic circuit, the capacitance value being adjusted in response to the control signal.
